(19) United States
(12) Patent Application Publication
(10) Pub. No.: US 2024/0049558 A1
(43) Pub. Date: Feb. 8, 2024

(54) DISPLAY PANEL AND DISPLAY DEVICE

(71) Applicant: Wuhan China Star Optoelectronics Semiconductor Display Technology Co., Ltd., Wuhan (CN)

(72) Inventors: Dong Zhan, Wuhan (CN); Hui Chen, Wuhan (CN)

(21) Appl. No.: 17/620,643

(22) PCT Filed: Dec. 10, 2021
(86) PCT No.: PCT/CN2021/136960

§ 371 Date: Dec. 17, 2021

(30) Foreign Application Priority Data
Nov. 24, 2021 (CN) 202111403807.6

(51) Int. Cl. H10K 59/80

(52) U.S. Cl. CPC H10K 59/80; H10K 59/8791

(57) ABSTRACT

The present application provides a display panel and a display device; the backplane of the display panel comprises a backplane main body and a structural reinforcement layer provided on a surface of the backplane main body, and the backplane main body adopts a material with high light transmittance arranged on the whole surface, and the structural reinforcement layer on the display substrate at least covers the active area. While ensuring the light transmittance of the functional area, it can also support and protect the display substrate of the corresponding functional area.

### FIELD OF THE INVENTION

The present application relates to a display technology field, and more particularly to a display panel and a display device.

### BACKGROUND OF THE INVENTION

With the development of display technology, organic light emitting diode (OLED) displays possess the characteristics of self-luminescence, wide viewing angle, short response time, high luminous efficiency, wide color gamut, low working voltage and flexibility, thus to be considered as the most potential new display device. OLED displays with high screen-to-body ratio are more popular with consumers. However, the front camera requires a transparent area for light to pass through the display. The screen cannot display images in this area, reducing the screen's screen-to-body ratio. In order to increase the screen-to-body ratio of the display screen, under screen camera technology appeared. Under screen camera technology requires digging holes on the back of the display to place the camera, such as an opening of the backplane on the back of the display at the position corresponding to the camera to increase the light transmittance. Then, the display at the opening part has no protection of the substrate, and the strength is low, and it is easy to be stabbed wounded.

Therefore, it is required to solve the problems of low strength and easy stabbing in the area of the existing OLED display corresponding to the under screen camera.

### SUMMARY OF THE INVENTION

The present application provides a display panel and a display device, to alleviate the technical problems of low intensity and easy stab wounds in the area of the existing OLED display corresponding to the under screen camera.

To solve the aforesaid problem, the technical solution of the present application is described as follows:

The embodiment of the present application provides a display panel, comprising: an active area and a functional area located in the active area, wherein the display panel further comprises:
a display substrate; and
a backplane attached to a back of the display substrate, comprising a backplane main body and a structural reinforcement layer provided on a surface of the backplane main body;
wherein an orthographic projection of the backplane main body on the display substrate covers the active area and the functional area, and an orthographic projection of the structural reinforcement layer on the display substrate at least covers the active area.

In the display panel provided by the embodiment of the present application, the structural reinforcement layer is arranged on a surface of the backplane main body facing the display substrate.

In the display panel provided by the embodiment of the present application, the structural reinforcement layer is arranged on a surface of the backplane main body away from the display substrate.

In the display panel provided by the embodiment of the present application, the orthographic projection of the structural reinforcement layer on the display substrate further covers the functional area.

In the display panel provided by the embodiment of the present application, phase differences of the structural reinforcement layer and the backplane main body are both less than or equal to 10.

In the display panel provided by the embodiment of the present application, a thickness of the structural reinforcement layer is greater than 0 micrometers and less than 20 micrometers.

In the display panel provided by the embodiment of the present application, a material of the backplane main body comprises at least one of Colorless Polyimide (CPI), Ultra Thin Glass (UTG), CycloOlefin Polymer (COP) and Triacetyl Cellulose (TAC).

In the display panel provided by the embodiment of the present application, the display panel further comprises a bonding area located on a side of the active area and a bending area located between the active area and the bonding area, and the bonding area is bent to the back of the display substrate through the bending area, wherein the backplane is broken at a position corresponding to the bending area, so that the backplane is divided into a first section backplane and second section backplane, and the first section backplane corresponds to the active area and the functional area, and the second section backplane corresponds to the bonding area.

In the display panel provided by the embodiment of the present application, the display panel further comprises an anti-reflection layer disposed on a side of the display substrate away from the backplane, and at a position close to the bending area, an end of the first section backplane and an end of the structural reinforcement layer are flush with or beyond an end of the anti-reflection layer.

In the display panel provided by the embodiment of the present application, the display panel further comprises a composite functional layer disposed on a side of the backplane away from the display substrate, and the composite functional layer is provided with an opening at a position corresponding to the functional area.

In the display panel provided by the embodiment of the present application, the embodiment of the present application further provides a display device, comprising a function element and the display panel of one of the foregoing embodiments, wherein the functional element is arranged on a side of the backplane away from the display substrate and arranged corresponding to the functional area.

The benefits of the present application are: in the display panel and the display device provided by the present application, the display panel comprises an active area and a functional area located in the active area. The display panel further comprises a display substrate and a backplane attached to a back of the display substrate. The backplane comprises a backplane main body and a structural reinforcement layer provided on a surface of the backplane main body. The backplane main body adopts a material with high light transmittance, and an orthographic projection of the backplane main body on the display substrate covers the active area and the functional area, and an orthographic projection of the structural reinforcement layer on the display substrate at least covers the active area. Accordingly, the backplane main body of the backplane is arranged on the whole surface. While ensuring the light transmittance of the functional area, it can also support and protect the display substrate of the corresponding functional area to solve the problems of low strength and easy stabbing in the area of the existing OLED display corresponding to the under screen camera. Meanwhile, the structural reinforcement layer can improve the strength and stiffness of the backplane main body and ensure the support performance of the backplane.

### BRIEF DESCRIPTION OF THE DRAWINGS

In order to more clearly illustrate the embodiments of the present invention and the prior art, the following figures will be described in the embodiments and the prior art are briefly introduced. It is obvious that the drawings are only some embodiments of the present invention, those of ordinary skill in this field can obtain other figures according to these figures without paying the premise.

FIG. 1 is a top view structural diagram of a display panel provided by an embodiment of the application.

FIG. 2 is a diagram of a cross-sectional structure of a display panel provided by an embodiment of the application.

FIG. 3 is a diagram of a cross-sectional structure of another display panel provided by an embodiment of the application.

FIG. 4 is a diagram of a cross-sectional structure of one another display panel provided by an embodiment of the application.

FIG. 5 is a diagram of a cross-sectional structure of one another display panel provided by an embodiment of the application.

FIG. 6 is a diagram of a cross-sectional structure of a display device provided by an embodiment of the application.

### DETAILED DESCRIPTION OF PREFERRED EMBODIMENTS

The following descriptions for the respective embodiments are specific embodiments capable of being implemented for illustrations of the present application with referring to appended figures. The terms of up, down, front, rear, left, right, interior, exterior, side, etcetera mentioned in the present application are merely directions of referring to appended figures. Thus, the used directional terms are used to describe and understand the present application, but the present invention is not limited thereto. In the figure, units with similar structures are denoted by the same reference numerals. In the figures, for clear understanding and convenient describing, the thickness of some layers and regions are exaggerated. That is, the size and thickness of each component shown in the figures are arbitrarily shown, but the application is not limited thereto.

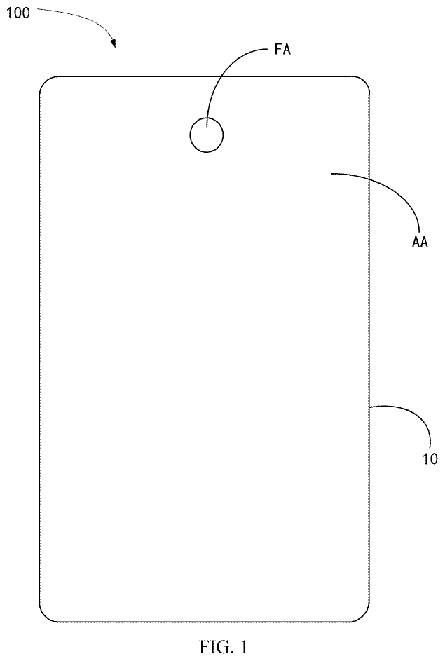

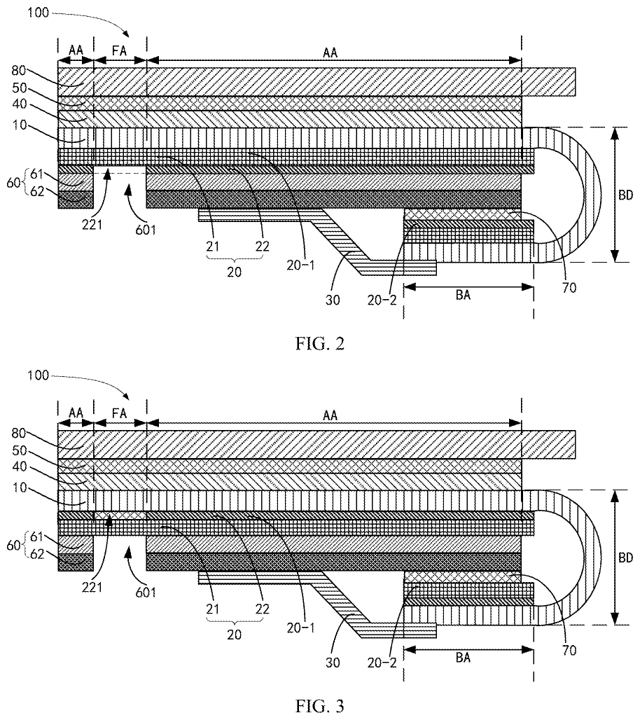

Please refer to FIG. 1 and FIG. 2. FIG. 1 is a top view structural diagram of a display panel provided by an embodiment of the application. FIG. 2 is a diagram of a cross-sectional structure of a display panel provided by an embodiment of the application. The display panel 100 comprises an active area AA and a functional area FA located in the active area AA. The active area AA refers to an area of the display panel 100 for displaying images. The functional area FA refers to an area of the display panel 100 for realizing functions such as camera. The function area FA to realize the camera function is illustrated for description in the present application. The functional area FA can be located anywhere in the active area AA. As the functional area FA is arranged in the active area AA while the functional area FA satisfies the functions of camera and other functions, it can also be employed to display images to realize the display function of the display panel 100, which can improve the screen-to-body ratio of the display panel 100.

Specifically, the display panel 100 further comprises a display substrate 10 and a backplane 20. The backplane 20 is attached to a back of the display substrate 10. The display substrate 10 is mainly employed to realize the display function of the display panel 100, and the backplane 20 is employed to support and protect the display substrate 10. The side of the display substrate 10 capable of displaying images is the light-emitting surface of the display substrate 10, and the side opposite to the light-emitting surface of the display substrate 10 is the back surface of the display substrate 10.

Optionally, the display panel 100 comprises an OLED display panel, a Micro LED display panel or a Mini LED display panel, etc. The OLED display panel is illustrated as the display panel 100. The display substrate 10 may comprise a base substrate, and a driving circuit layer, a light-emitting function layer and an encapsulation layer stacked on the base substrate.

The backplane 20 is attached to the back surface of the display substrate 10. The backplane 20 comprises a backplane main body 21 and a structural reinforcement layer 22 provided on a surface of the backplane main body 21. An orthographic projection of the backplane main body 21 on the display substrate 10 covers the active area AA and the functional area FA, and an orthographic projection of the structural reinforcement layer 22 on the display substrate 10 at least covers the active area AA.

Specifically, a material of the backplane main body 21 comprises at least one of Colorless Polyimide (CPI), Ultra Thin Glass (UTG), CycloOlefin Polymer (COP), Triacetyl Cellulose (TAC) and other materials with high light transmittance. The phase difference of the backplane main body 21 is less than or equal to 10, and there is no anisotropy.

It is understandable that the conventional backplane structure usually adopts a polyethylene terephthalate (PET) substrate that is arranged on the entire surface. However, the phase difference of polyethylene terephthalate is relatively high, and it is easy to produce a photoelastic effect due to strain during the bonding process of the backplane, that is, birefringence occurs when light passes through the backplane. As a result, an undesirable phenomenon similar to water ripple occurs as taking pictures, which affects the photographing effect of the under screen camera. In order to avoid the water ripple phenomenon, an opening can be prepared on the backplane corresponding to the camera function area. However, this will cause new problems. For instance, the display substrate corresponding to the opening may collapse due to no supporting structure, and the display substrate corresponding to the opening may be easily stabbed wounded due to the lack of the protective structure.

In the present application, materials with high light transmittance and small phase difference are employed to prepare the backplane main body 21. The backplane main body 21 is arranged on the entire surface, which not only meets the requirements of the function area FA for the light transmittance of functions such as photographing, but also avoids the phenomenon of water ripples. Meanwhile, the display substrate 10 corresponding to the functional area FA can be supported and protected, and the display substrate 10 in this area can be prevented from collapsing or being stabbed due to lack of support and protection.

However, Colorless Polyimide, CycloOlefin Polymer and other materials with high light transmittance and small phase difference make that he support property of the backplane main body 21 made of these materials is poor due to the poor strength and low stiffness of the material itself. Thus, the backplane 20 of the present application further comprises a structural reinforcement layer 22 provided on the surface of the backplane main body 21 away from the display substrate 10.

Specifically, the structural reinforcement layer 22 is disposed on the lower surface of the backplane main body 21. The surface of the backplane main body 21 facing the display substrate 10 is the upper surface of the backplane main body 21, and the surface opposite to the upper surface of the backplane main body 21 is the lower surface of the backplane main body 21. The structural reinforcement layer 22 may be formed on the lower surface of the backplane main body 21 by coating, spraying, physical vapor deposition (PVD), chemical vapor deposition (Chemical Vapor Deposition, CVD), etc. to reinforce the structure of the back plate main body 21 for increasing the hardness of the backplane main body 21, thereby improving the supporting property of the backplane 20. The backplane main body 21 can be attached to the display substrate 10 through an optically clear adhesive (OCA) and other highly translucent adhesive materials.

Optionally, an orthographic projection of the structural reinforcement layer 22 on the display substrate 10 covers the active area AA. A first opening 221 is provided at a position corresponding to the functional area FA. Since the structural reinforcement layer 22 does not block the functional area FA, this design has no special requirements on the light transmittance and the phase difference of the material of the structural reinforcement layer 22 as long as the structural reinforcement layer 22 possesses a relatively high hardness to be able to realize the structural reinforcement of the backplane main body 21.

Meanwhile, in order to realize the flexibility of the display panel 100, while the structural reinforcement layer 22 is provided to improve the supporting property of the backplane 20, the flexibility of the backplane 20 should also be taken into consideration. Therefore, a thinner structural reinforcement layer 22 can be provided. Optionally, the thickness of the structural reinforcement layer 22 is greater than 0 micrometers and less than 20 micrometers.

Besides, the display panel 100 further comprises a bonding area BA located on a side of the active area AA and a bending area BD located between the active area AA and the bonding area BA, and the bonding area BA is bent to the back of the display substrate 10 through the bending area BD. The display substrate 10 is designed with various fan-out lines in the bending area BD for connecting with various signal lines of the display substrate 10 in the active area AA; the display substrate 10 is designed with a bonding terminal in the bonding area BA, and one end of the bonding terminal is connected with the fan-out line of the bending area BD, and the other end is bound with a driver or a flexible printed circuit board (FPC) 30 to provide driving signals to the display substrate 10.

Optionally, the display panel 100 further comprises a protective layer. The protective layer comprises UV glue and the like. The protective layer covers the bending area BD of the display substrate 10 and extends toward both ends of the bending area BD to protect the fan-out lines of the bending area BD and avoid the line breaks in the bending zone BD during bending.

The backplane 20 is broken at a position corresponding to the bending area BD, so that the backplane 20 is divided into a first section backplane 20-1 and second section backplane 20-2, and the first section backplane 20-1 corresponds to the active area AA and the functional area FA, and the second section backplane 20-2 corresponds to the bonding area BA. After the bonding area BA is bent to the back of the display substrate 10, the first section backplane 20-1 and the second section backplane 20-2 face to each other. The first section backplane 20-1 and the second section backplane 20-2 are flush with the end of the bending zone BD. Besides, since the backplane 20 comprises a backplane main body 21 and a structural reinforcement layer 22 provided on the surface of the backplane main body 21, the backplane 20 possesses a strong supporting property, thereby improving the supporting capacity of the display substrate in the bending area BD, and avoiding a circuit break (crack) of the display substrate at the position of the bending fixed end. The bending fixed end of the display substrate 10 refers to a horizontal area connected to the bending start end of the bending area BD. The display substrate 10 in this area bears greater bending stress, and it is necessary to provide sufficient supporting force to the backplane 20 in the corresponding area to prevent the display substrate 10 in this area from collapsing and deforming, which may cause circuit break in this area.

Furthermore, the display panel 100 further comprises an anti-reflection layer 40 disposed on a side of the display substrate 10 away from the backplane 20. The anti-reflection layer 40 comprises a polarizer, a color filter or other optical film layers that can reduce reflectivity. The anti-reflective layer 40 is attached to the light-emitting surface of the display substrate 10 by an Optically Clear Adhesive (OCA) or the like. When ambient light is incident on the display panel 100, the anti-reflection layer 40 can absorb part of the ambient light and prevent the ambient light from being reflected by the metal lines inside the display substrate 10, so as to reduce the reflectivity and improve the contrast of the display panel 100.

Optionally, at a position close to the bending area BD, an end of the first section backplane 20-1 and an end of the structural reinforcement layer 22 are flush with or beyond an end of the anti-reflection layer 40. Thus, the supporting property of the backplane 20 to the display substrate 10 in the bending area BD can be further improved.

Furthermore, the display panel 100 further comprises a composite functional layer 60 disposed on a side of the backplane 20 away from the display substrate 10, and the composite functional layer 60 is provided with a second opening 601 at a position corresponding to the functional area FA to avoid affecting the light transmittance of the functional area FA. The size of the second opening 601 is the same as the size of the first opening 221. As shown in FIG. 2, the second opening 601 and the first opening 221 are separated by a dotted line for showing distinction.

Optionally, the composite functional layer 60 comprises a first functional layer 61 and a second functional layer 62. The first functional layer 61 comprises foam materials such as foam. The foam possesses moderate mechanical strength, is bendable, and possesses weaker bending property than the display substrate 10, which can strengthen the supporting force for the display substrate 10 and avoid local stress concentration. At the same time, the foam possesses a better heat insulation effect, which can prevent the heat generated by the driver and the external line from affecting the active area AA. The first functional layer 61 can be attached to the surface of the first section backplane 20-1 away from the display substrate 10 through an adhesive material, such as an embo. The embo possesses the advantages of easy bonding and venting. The use of embo for bonding can avoid undesirable phenomena, such as bubbles and bulges during bonding.

The second functional layer 62 is attached to the side of the first functional layer 61 away from the first section backplane 20-1, and the second functional layer 62 comprises copper foil, a copper foil composite film and the like. The copper foil composite film can be formed by laminating polyimide (PI) with glue, a glue material and copper foil. The PI in the copper foil composite film is mainly employed to increase the overall rigidity of the composite functional layer 60 to increase the compression resistance of the back of the display substrate 10. Copper foil possesses excellent electrical conductivity, which can achieve better electromagnetic shielding effect. Meanwhile, copper foil also possesses good thermal conductivity, which can realize rapid heat transfer, and transfer heat in local high temperature areas to other places, which is convenient for uniform heat distribution and heat dissipation.

In addition, the second section backplane 20-2 is attached to the side of the second functional layer 62 away from the first functional layer 61 through a double-sided adhesive tape such as a composite tape 70 to fix the part of the display substrate 10 located in the bonding area BA. The composite tape 70 may be a double-sided adhesive stiffener, and the bending radius of the bending area BD can be adjusted by adjusting the height of the composite tape 70.

Certainly, the display panel 100 may further comprise a structure such as a cover plate 80 provided on the light-emitting side of the display substrate 10. The cover can be attached to the side of the anti-reflection layer 40 away from the display substrate 10 through optically clear adhesive (OCA) 50, etc., to protect the display substrate 10 and the anti-reflection layer 40.

Optionally, the display panel 100 of the present application may further comprise a touch function layer (not shown) disposed between the anti-reflection layer 40 and the display substrate 10, and the touch function layer is directly disposed on the display substrate 10. A DOT touch solution is adopted to realize the touch function. Alternately, the display panel 100 of the present application may also adopt an external touch solution.

In this embodiment, materials with high light transmittance and small phase difference are employed to prepare the backplane main body 21 of the backplane 20. The backplane main body 21 is arranged on the entire surface, which not only meets the requirements of the function area FA for the light transmittance of functions such as photographing, but also avoids the phenomenon of water ripples. Meanwhile, the display substrate 10 corresponding to the functional area FA can be supported and protected, and the display substrate 10 in this area can be prevented from collapsing or being stabbed due to lack of support and protection. Meanwhile, the structural reinforcement layer 22 is disposed on the surface of the backplane main body 21 to reinforce the structure of the back plate main body 21 for increasing the hardness of the backplane main body 21, thereby improving the supporting property of the backplane 20. Particularly, the supporting capacity of the display substrate 10 provided by the backplane 20 in the bending area BD is improved to avoid a crack of the display substrate 10 at the position of the bending fixed end.

In an embodiment, referring to FIG. 3, FIG. 3 is a diagram of a cross-sectional structure of another display panel provided by an embodiment of the application. The difference from the foregoing embodiment is that the structural reinforcement layer 22 is provided on the surface of the backplane main body 21 facing the display substrate 10, and the structural reinforcement layer 22 is provided with the first opening 221 at a position corresponding to the functional area FA. The structural reinforcement layer 22 is attached to the back of the display substrate 10 through the optically clear adhesive (OCA) or pressure sensitive adhesive (PSA), etc., and preferably the optically clear adhesive is selected. Because of the existence of the first opening 221, there is a gap between the display substrate 10 corresponding to the functional area FA and the backplane main body 21, and when the optically clear adhesive is used, the optically clear adhesive can be filled in the first opening 221. This does not only affect the light transmittance of the functional area FA, but also improves the support requirements for the display substrate 10 in this area. Meanwhile, the structure of the backplane 20 of this embodiment can achieve the same effect as the aforesaid embodiment. For other descriptions, please refer to the aforesaid embodiment, which will not be repeated here.

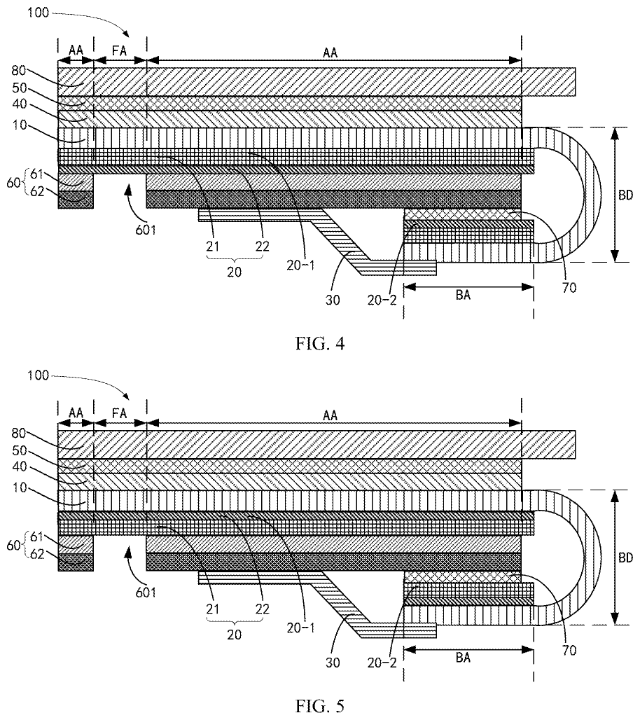

In an embodiment, referring to FIG. 4, FIG. 4 is a diagram of a cross-sectional structure of one another display panel provided by an embodiment of the application. The difference from the foregoing embodiment is that the orthographic projection of the structural reinforcement layer 22 on the display substrate 10 also covers the functional area FA, that is, the structural reinforcement layer 22 and the backplane main body 21 are both designed as an entire surface. Specifically, the structural reinforcement layer 22 is disposed on the lower surface of the backplane main body 21. In order to prevent the structural reinforcement layer 22 from affecting the light transmittance of the functional area FA, an optically clear material may be employed to coat the lower surface of the backplane main body 21 to form the structural reinforcement layer 22. Meanwhile, in order to avoid water ripples, the phase difference of the structural reinforcement layer 22 is less than or equal to 10, and there is no anisotropy. Moreover, the entire surface arrangement of the structural reinforcement layer 22 can also enhance the supporting property of the backplane 20 at the position corresponding to the functional area FA. Thus, the supporting property of the backplane 20 to the display substrate 10 in this area is improved, and the display substrate 10 corresponding to the functional area FA is prevented from collapsing. For other descriptions, please refer to the aforesaid embodiment, which will not be repeated here.

In an embodiment, referring to FIG. 5, FIG. 5 is a diagram of a cross-sectional structure of one another display panel provided by an embodiment of the application. The difference from the foregoing embodiment is that the orthographic projection of the structural reinforcement layer 22 on the display substrate 10 also covers the functional area FA and the structural reinforcement layer 22 is provided on the upper surface of the backplane main body 21. Accordingly, the same effect as the foregoing embodiment can be achieved. For other descriptions, please refer to the foregoing embodiment, which will not be repeated here.

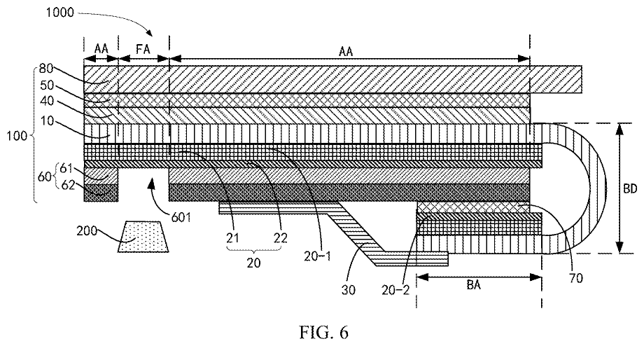

In an embodiment, referring to FIG. 6, FIG. 6 is a diagram of a cross-sectional structure of a display device provided by an embodiment of the application. The display device 1000 comprises electronic devices such as mobile phones, tablets and televisions. Specifically, the display device 1000 comprises a function element 200 and the display panel 100 of one of the foregoing embodiments. The function element 200 is disposed on the side of the backplane 20 away from the substrate 10, and is provided corresponding to the functional area FA.

The function element 200 comprises a camera and the like. A camera is illustrated as the function element 200, and the active area AA of the display panel 100 is employed to present a display state; the functional area FA can present a display state and a light-transmitting state. When the active area AA is in the display state and the functional area FA is also in the display state, the display substrate 10 corresponding to the active area AA and the functional area FA performs display functions, and the camera is turned off. The display device 1000 realizes a full-screen display. When the active area AA is in the display state and the functional area FA is in the light-transmitting state, the display substrate 10 corresponding to the active area AA performs the display function, and the display substrate 10 corresponding to the functional area FA does not perform the display function. The ambient light can pass through respective film layers corresponding to the functional area FA and enter the camera located on the back of the display substrate 10. When the camera is turned on, the display device realizes a photographing function, and transmits the images taken by the camera to the active area AA of the display panel 100 for display.

It can be known according to the aforesaid embodiment:

The present application provides a display panel and a display device. The display panel comprises an active area and a functional area located in the active area. The display panel further comprises a display substrate and a backplane attached to a back of the display substrate. The backplane comprises a backplane main body and a structural reinforcement layer provided on a surface of the backplane main body. The backplane main body adopts a material with high light transmittance, and an orthographic projection of the backplane main body on the display substrate covers the active area and the functional area, and an orthographic projection of the structural reinforcement layer on the display substrate at least covers the active area. Accordingly, the backplane main body of the backplane is arranged on the whole surface. While ensuring the light transmittance of the functional area, it can also support and protect the display substrate of the corresponding functional area to solve the problems of low strength and easy stabbing in the area of the existing OLED display corresponding to the under screen camera. Meanwhile, the structural reinforcement layer can improve the strength and stiffness of the backplane main body and ensure the support performance of the backplane.

In the foregoing embodiments, the description of the various embodiments have respective different emphases, and a part in some embodiment, which is not described in detail can be referred to the related description of other embodiments.

The embodiment of the present application is described in detail as aforementioned, and the principles and implementations of the present application have been described with reference to specific illustrations. The description of the foregoing embodiments is merely for helping to understand the technical solutions of the present application and the core ideas thereof; those skilled in the art should understand that the technical solutions described in the foregoing embodiments may be modified, or some of the technical features may be equivalently replaced; and the modifications or replacements do not deviate from the spirit and scope of the technical solutions of the embodiments of the present application.

What is claimed is:

1. A display panel, comprising: an active area and a functional area located in the active area, wherein the display panel further comprises:
a display substrate; and
a backplane attached to a back of the display substrate, comprising a backplane main body and a structural reinforcement layer provided on a surface of the backplane main body;
wherein an orthographic projection of the backplane main body on the display substrate covers the active area and the functional area, and an orthographic projection of the structural reinforcement layer on the display substrate at least covers the active area.

2. The display panel according to claim 1, wherein the structural reinforcement layer is arranged on a surface of the backplane main body facing the display substrate.

3. The display panel according to claim 1, wherein the structural reinforcement layer is arranged on a surface of the backplane main body away from the display substrate.

4. The display panel according to claim 1, wherein the orthographic projection of the structural reinforcement layer on the display substrate further covers the functional area.

5. The display panel according to claim 4, wherein phase differences of the structural reinforcement layer and the backplane main body are both less than or equal to 10.

6. The display panel according to claim 5, wherein a thickness of the structural reinforcement layer is greater than 0 micrometers and less than 20 micrometers.

7. The display panel according to claim 5, wherein a material of the backplane main body comprises at least one of transparent polyimide, ultra-thin glass, cycloolefin polymer and cellulose triacetate.

8. The display panel according to claim 4, wherein the display panel further comprises a bonding area located on a side of the active area and a bending area located between the active area and the bonding area, and the bonding area is bent to the back of the display substrate through the bending area, wherein the backplane is broken at a position corresponding to the bending area, so that the backplane is divided into a first section backplane and second section backplane, and the first section backplane corresponds to the active area and the functional area, and the second section backplane corresponds to the bonding area.

9. The display panel according to claim 8, wherein the display panel further comprises an anti-reflection layer disposed on a side of the display substrate away from the backplane, and at a position close to the bending area, an end of the first section backplane and an end of the structural reinforcement layer are flush with or beyond an end of the anti-reflection layer.

10. The display panel according to claim 4, wherein the display panel further comprises a composite functional layer disposed on a side of the backplane away from the display substrate, and the composite functional layer is provided with an opening at a position corresponding to the functional area.

11. A display device, comprising a function element and a display panel, wherein the display panel comprises an active area and a functional area located in the active area, wherein the display panel further comprises:
a display substrate; and
a backplane attached to a back of the display substrate, comprising a backplane main body and a structural reinforcement layer provided on a surface of the backplane main body;
wherein an orthographic projection of the backplane main body on the display substrate covers the active area and the functional area, and an orthographic projection of the structural reinforcement layer on the display substrate at least covers the active area; the functional element is arranged on a side of the backplane away from the display substrate and arranged corresponding to the functional area.

12. The display panel according to claim 11, wherein the structural reinforcement layer is arranged on a surface of the backplane main body facing the display substrate.

13. The display panel according to claim 11, wherein the structural reinforcement layer is arranged on a surface of the backplane main body away from the display substrate.

14. The display panel according to claim 11, wherein the orthographic projection of the structural reinforcement layer on the display substrate further covers the functional area.

15. The display panel according to claim 14, wherein phase differences of the structural reinforcement layer and the backplane main body are both less than or equal to 10.

16. The display panel according to claim 15, wherein a thickness of the structural reinforcement layer is greater than 0 micrometers and less than 20 micrometers.

17. The display panel according to claim 15, wherein a material of the backplane main body comprises at least one of transparent polyimide, ultra-thin glass, cycloolefin polymer and cellulose triacetate.

18. The display panel according to claim 14, wherein the display panel further comprises a bonding area located on a side of the active area and a bending area located between the active area and the bonding area, and the bonding area is bent to the back of the display substrate through the bending area, wherein the backplane is broken at a position corresponding to the bending area, so that the backplane is divided into a first section backplane and second section backplane, and the first section backplane corresponds to the active area and the functional area, and the second section backplane corresponds to the bonding area.

19. The display panel according to claim 18, wherein the display panel further comprises an anti-reflection layer disposed on a side of the display substrate away from the backplane, and at a position close to the bending area, an end of the first section backplane and an end of the structural reinforcement layer are flush with or beyond an end of the anti-reflection layer.

20. The display panel according to claim 14, wherein the display panel further comprises a composite functional layer disposed on a side of the backplane away from the display substrate, and the composite functional layer is provided with an opening at a position corresponding to the functional area.
